(19) United States
(12) Patent Application Publication
(10) Pub. No.: US 2019/0006154 A1
(43) Pub. Date: Jan. 3, 2019

(54) Toroidal Plasma Chamber

(71) Applicant: Chaolin Hu, North Billerica, MA (US)

(72) Inventor: Chaolin Hu, North Billerica, MA (US)

(21) Appl. No.: 15/635,592

(22) Filed: Jun. 28, 2017

(51) Int. Cl. H01J 37/32; C22C 21/10; C22C 21/06; C22F 1/053; C22F 1/047; C22F 1/00; B22D 21/00; B22D 25/02

(52) U.S. Cl. CPC H01J 37/32467; C22C 21/10; C22C 21/06; C22F 1/053; H01J 37/3211; C22F 1/002; B22D 21/007; B22D 25/02; H01J 37/3244; C22F 1/047

(57) ABSTRACT

An apparatus and methods for forming a toroidal plasma chamber includes metallic material, material forming process, heat treatment, anodization and a feature to form an ideal gas flow pattern in the plasma chamber. The gas passing through the plasma chamber that functions as a secondary wiring in a transformer will be dissociated when coupled with the current induced through a magnetic core by a primary wiring that is a semiconductor switching power source.

### FIELD OF THE INVENTION

This invention relates generally to the field of generating activated gas containing ions, free radicals, atoms and molecules and to apparatus for and methods of processing materials with activated gas.

### BACKGROUND OF THE INVENTION

Plasma discharges can be used to excite gases to produce activated gases containing ions, free radicals, atoms and molecules. Activated gases are used for numerous industrial and scientific applications including processing solid materials such as semiconductor wafers, powders, and other gases. The parameters of the plasma and the conditions of the exposure of the plasma to the material being processed vary widely depending on the application.

For example, some applications require the use of ions with low kinetic energy (i.e. a few electron volts) because the material being processed is sensitive to damage. Other applications, such as anisotropic etching or planarized dielectric deposition, require the use of ions with high kinetic energy. Still other applications, such as reactive ion beam etching, require precise control of the ion energy.

Some applications require direct exposure of the material being processed to a high density plasma. One such application is generating ion-activated chemical reactions. Other such applications include etching of and depositing material into high aspect ratio structures. Other applications require shielding the material being processed from the plasma because the material is sensitive to damage caused by ions or because the process has high selectivity requirements.

Plasmas can be generated in various ways, including DC discharge, radio frequency (RF) discharge, and microwave discharge. DC discharges are achieved by applying a potential between two electrodes in a gas. RF discharges are achieved either by electrostatically or inductively coupling energy from a power supply into a plasma.

Parallel plates are typically used for electrostatic ally coupling energy into a plasma. Induction coils are typically used for inducing current into the plasma. Microwave discharges are achieved by directly coupling microwave energy through a microwave-passing window into a discharge chamber containing a gas. Microwave discharges are advantageous because they can be used to support a wide range of discharge conditions, including highly ionized electron cyclotron resonant (ECR) plasmas.

RF discharges and DC discharges inherently produce high energy ions and, therefore, are often used to generate plasmas for applications where the material being processed is in direct contact with the plasma. Microwave discharges produce dense, low ion energy plasmas and, therefore, are often used to produce streams of activated gas for “downstream” processing. Microwave discharges are also useful for applications where it is desirable to generate ions at low energy and then accelerate the ions to the process surface with an applied potential. However, microwave and inductively coupled plasma sources require expensive and complex power delivery systems. These plasma sources require precision RF or microwave power generators and complex matching networks to match the impedance of the generator to the plasma source. In addition, precision instrumentation is usually required to ascertain and control the actual power reaching the plasma.

RF inductively coupled plasmas are particularly useful for generating large area plasmas for such applications as semiconductor wafer processing. However, prior art RF inductively coupled plasmas are not purely inductive because the drive currents are only weakly coupled to the plasma. Consequently, RF inductively coupled plasmas are inefficient and require the use of high voltages on the drive coils. The high voltages produce high electrostatic fields that cause high energy ion bombardment of reactor surfaces. The ion bombardment deteriorates the reactor and can contaminate the process chamber and the material being processed. The on bombardment can also cause damage to the material being processed.

A toroidal plasma applicator has been invented to provide a source of activated gas that uses a high efficiency RF power coupling device which couples power into a plasma without the use of conventional RF or microwave generators and impedance matching systems. Another advantage of this plasma source is that there is no significant energetic ion bombardment within the process reactor where long-term operation can be sustained using chemically reactive gases without damage to the source and without production of contaminant materials. Either a metal, a dielectric, or a coated metal (e.g. anodized) can be used to form the source chamber.

This plasma source has found applications in new areas such as on-chamber wafer processes, due to its low energy ion bombardment to meet the requirements for not damaging the chip structures. When it is used for an on-chamber application, the toroidal plasma chamber may be used as a stand-along source. Alternatively, the wafer process chamber may be used as part of the toroidal source to form a loop for the required applications. The latter may minimize the traveling distance of the activated gas and reduce unnecessary loss of plasma. As the semiconductor industry continues to develop thinner, denser and more functional chips, the demand for processes using this plasma source will be increasing. It may be anticipated that this toroidal plasma source will be much more widely used for thin film deposition, precise stripping, thin film forming and such.

This plasma source includes a semiconductor switching power source coupling a RF potential through a primary wiring in a transformer, a magnetic core, and a toroidal plasma chamber as a secondary wiring. The current driven by the primary wiring induces the potential in the toroidal plasma chamber that forms a plasma which completes the secondary circuit of the transformer, dissociates the gas passing through the chamber and produces a combination of ions, free radicals, atoms, and molecules for different applications. It has been widely used in wafer fabrication such as stripping and chamber cleaning processes.

An ideal toroidal plasma chamber needs to have a smooth passage for the induced current and the active gas being processed. The current has a tendency to pass on the inner surface of the chamber and therefore any sharp corner in the chamber may result in an undesired damage to the surface and cause contamination. The coating on the chamber surface needs to be compatible with the active gas and with a required dielectric property so the current can be induced in the gas but not in the solid material that forms the chamber.

The currently available toroidal plasma sources use a wright aluminum alloy such as Al 6061 or Al 6063 as the material of the plasma chamber because these alloys can be easily anodized to form a thick and dense oxide surface that is required for a plasma chamber. The existing technology is to use machined parts of these materials and then have their inner surface anodized. However, due to the difficulty encountered in the machining of such a complex inner surface, the toroidal plasma sources available in market have inevitable sharp corners and undesired passage in their plasma chambers. These sharp corners and uneven gas passage have been the root cause of undesired particle generation, surface degradation and early failures.

There are in general two major interactions between the plasma and chamber inner surface that lead to these severe damages to the plasma chamber. The first one is the chamber erosion due to the collision of an induced current with the inner surface of chamber. This often happens at sharp corners and uneven surface of the chamber and as a result, a considerable amount of the plasma energy is transferred into the chamber material and react with it that finally damages the chamber surface.

The second plasma chamber interaction is closely related to the degree of gas dissociation rate and the higher the degree of the gas being dissociated, the higher the erosion of the chamber due to a stronger reaction between the activated gas and the chamber. Therefore the severe chamber erosion occurs at the locations toward the exit of the chamber where the gas dissociation rate is the highest. Furthermore, since the gas dissociation rate depends on the injected gas conditions such as the gas flow rate and pressure for a given chamber and power supply, the erosion of a chamber also depends on the gas conditions. So, a gas that is fully dissociated at a much earlier stage in the chamber may cause more chamber damage, which may also result from a higher power supply, a slow gas flow or too long a plasma chamber, or a combination of them.

Furthermore, with an increasing use of more aggressively active gas in IC fabrication such as chromium and hydrogen, the long used and widely accepted coatings such as anodization are no longer well compatible with the these applications. As a result of it, the dielectric property of the coating changes with the time in the process and leads to a varying chamber surface recombination rate and therefore a varying final concentration of ions, free radicals, atoms and molecules, which has made such a process difficult to control. So far, there is no sufficient coating available with a dielectric property stable for even a short period of time when processing a very aggressive active gas.

### SUMMARY OF THE INVENTION

The subject matter of this application may involve, in some cases, interrelated products, alternative solutions to a particular problem, and/or a plurality of different uses of a single system or article.

It is therefore a principal object of this invention to provide a metallic forming method that allows for the formation of a desired shape and size of a toroidal plasma chamber without any sharp corners or curve in its inner surface.

It is another principal object of this invention to provide a metallic material that when associated with the forming method selected can be coated with a dielectric layer on its inner surface that is also relatively compatible with active gasses.

It is still another principal object of this invention to provide a feature in this metallic plasma chamber that will force the injected gas to flow in such a specific pattern to keep the induced current from the inner surface of the chamber therefore to protect the chamber.

It is still another principal object of this invention to build a toroidal plasma chamber with an integrated gas injection system that can inject a fresh gas along the gas path and therefore to protect the chamber all the way from the inlet to outlet. This protection functions as an additional layer to protect the plasma chamber, enhance the chamber's service life and make the process more stable and reliable.

This apparatus may include a metallic component that is part of a toroidal plasma chamber and may be formed using a metal casting process, in which a liquid of the metallic material is poured into a mold that usually contains a hollow cavity of the desired shape and then allowed to solidify. This casting process allows for making complex toroidal plasma chamber contour that would be otherwise difficult or uneconomical to make by other methods. The casting process could be a sand, mold, die or any other casting processes. The casting process would have been long used to form a toroidal plasma chamber if the finally formed metal component could satisfy all the requirements for a later performed dielectric coating process and the formed coating could provide all required functions.

If a metallic component in the apparatus is formed using a metallic casting process, it may be made of an aluminum based casting alloys that contains a relatively large amount of elements such as Mg, Zn or similar. Elements like Mg and Zn are listed in the galvanic series over Al at the anodic side and will have a higher tendency to be anodized than Al. So, using an alloy such as Al—Mg, Al—Zn, Al—Mg—Zn or such will make it possible to form a full dense anodization layer with uniformly distributed microstructures. Obviously, it is impossible for the most popular Al—Si casting alloy system.

This apparatus may also include a metallic component that is part of a toroidal plasma chamber and may be formed using a tube bending process, in which an appropriate size of aluminum tube is bent to form the toroidal plasma chamber. In this case, the material may be a wright aluminum alloy such as 6061 or 6063 or similar. Since these alloys have been long accepted as the best choice of materials for the following anodization process, they naturally satisfy all the requirements for a following inner surface anodization process. If this is the case, a welding or joining process may be associated to integrate all the required parts for a fully functional toroidal plasma chamber.

The apparatus may include a component that can be either made of a metal or dielectric material. This component may be inserted into the gas loop as an injector to force a gas to enter the chamber at a tangent angle to the inner wall. The component may include a number of injectors in symmetric orientations to the central line of the gas loop to make a swirling gas flow pattern that will keep the plasma from the chamber inner wall and protect the plasma chamber. This capability will add to the coating compatibility with reactive gas being process.

If a component of the toroidal plasma chamber is made through a bending process with associated machining and welding, an integrated gas injection system can be built in the chamber that can inject a gas in a later stage in the gas path to protect the chamber all the way to the exit.

### BRIEF DESCRIPTION OF THE DRAWINGS

This invention is described with particularity in the appended claims. The above and further advantages of this invention may be better understood by referring to the following description taken in conjunction with the accompanying drawings, in which:

FIG. 1 is a schematic representation of a toroidal plasma source for producing activated gases in which the plasma chamber embodies the invention.

FIG. 2 illustrates inevitable sharp corners in a typical prior art toroidal plasma chamber that may result in disturbed air flow, erode the chamber quickly and cause early stage contamination.

FIG. 3 is the Al—Si phase diagram showing the eutectic composition of Al 87.4 w %/Si 12.6 w % and a melting point of 577° C. at which Si has its maximum solubility of 1.65 w % in an Al solid solution.

FIG. 4 is a galvanic series showing that the elements such as Mg and Zn are listed over Al on the anodic side and have a higher tendency to being anodized in the coating process.

FIG. 5 is the Al—Mg phase diagram showing the eutectic composition of Al 63.9 w %/Mg 36.1 w % and a melting point of 450° C. at which Mg has its maximum solubility of 17.1 w % in an Al solid solution.

FIG. 6 is a schematic representation of an invented toroidal plasma chamber with an ideal shape of gas loop, no sharp corners or uneven surface, which is formed using a metallic casting process.

FIG. 7 is a schematic representation of an invented toroidal plasma chamber used for an on-chamber wafer application, in which the wafer process chamber is utilized as part of the induced current loop to form plasma.

FIG. 8A is a schematic representation of a component in the invention that may contain a number of groups of injectors in symmetric orientations to the central line of the gas loop.

FIG. 8B is a cross section of the injectors showing symmetric orientations of the injectors at area A of FIG. 8A.

FIG. 9 is a schematic presentation of three typical gas dissociation profiles as a function of the distance along the gas traveling path in a toroidal plasma chamber, depending on the power supply, gas conditions and plasma chamber size.

FIG. 10 is a schematic representation of the top part of a toroidal plasma chamber made of three separate pieces, assembled into an integrated toroidal plasma chamber.

FIG. 11 is a schematic representation of a section view of a toroidal plasma chamber.

FIG. 12A is a schematic illustration of an integrated gas injection system that can inject gas all the way in the plasma chamber, from the top to the exit of the chamber.

FIG. 12B is a schematic view of the cross section of the gas injection at these locations in which gas is injected in symmetric orientations to the tube central line at areas A, B, and C, of FIG. 12A.

FIG. 13 is schematic toroidal plasma chamber formed using a combined casting and tube bending process.

### DETAILED DESCRIPTION

The detailed description set forth below in connection with the appended drawings is intended as a description of presently preferred embodiments of the invention and does not represent the only forms in which the present invention may be constructed and/or utilized. The description sets forth the functions and the sequence of steps for constructing and operating the invention in connection with the illustrated embodiments.

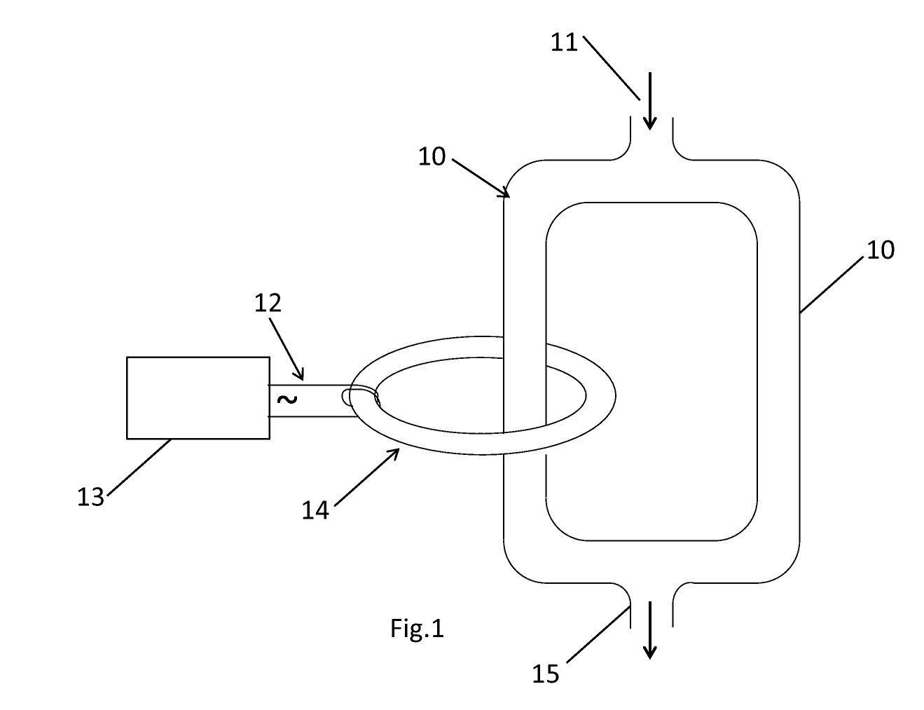

FIG. 1 is a schematic representation of a toroidal plasma source for producing activated gases in which the toroidal plasma chamber embodies the invention. The source includes a power transformer that couples electromagnetic energy into a plasma. The power transformer includes a RF power source, a high permeability magnetic core, a primary coil, and a plasma chamber which allows the plasma to form a secondary circuit of the transformer.

This chamber is where the RF power is coupled through a transformer and a reactive gas is activated by the induced current or electrons, large molecules are broken, some ionized and some form small molecules or radicals. The activated gas may aggressively erode the coating layer of the chamber and change its dielectric property. As a result of it, a dielectric property varying coating may lead to a varying concentration of the activated gas, which makes the whole activated gas process difficult to control. Another result is a severely damaged coating layer from which particles are peeled, leading to the contamination the chamber and wafer.

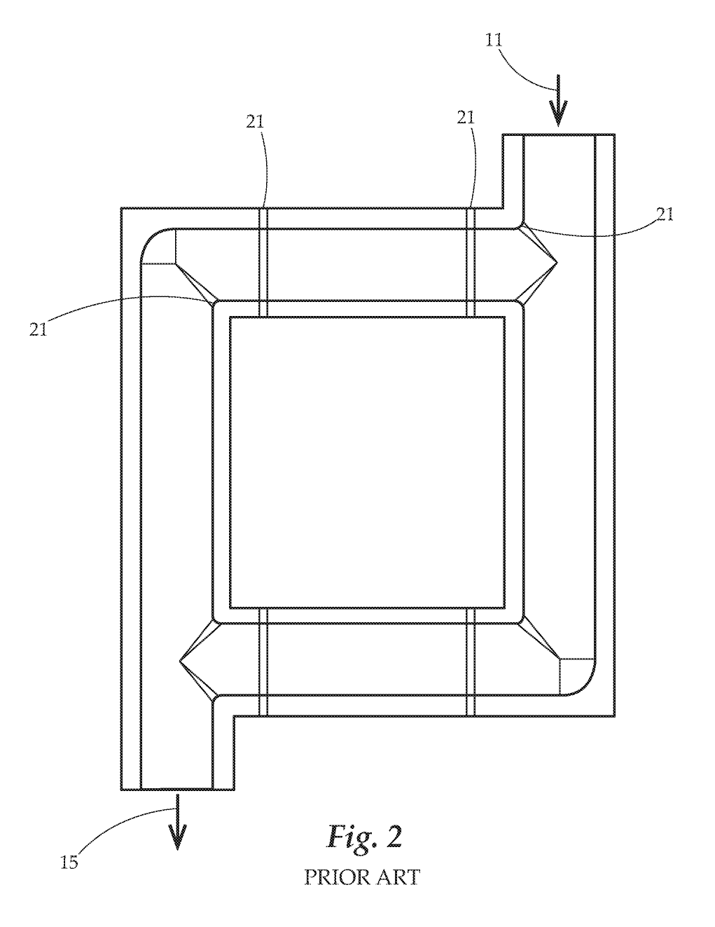

FIG. 2 is a schematic representation of a typical prior art toroidal plasma chamber that may be made of a metallic material such as an aluminum alloy. The inner surface of the chamber is coated with a dielectric layer that should be also compatible with the activated gas. The existing technology that has long been accepted is the use of machined parts of a wright aluminum alloy such as Al 6061 or Al 6063, followed with a surface anodization process. However, due to the difficulties encountered in the machining for a desired smooth shape of gas passage in the chamber, it is inventible to have sharp corners or uneven surface in the chamber that may cause unexpected gas turbulence, strong interaction between the activated gas and chamber and early chamber erosion.

One of the approaches in this invention is to use a metal casting process, in which a liquid of the metallic material is poured into a mold that usually contains a hollow cavity of the desired shape and then allowed to solidify. This casting process allows for making a complex toroidal plasma chamber contour that would be otherwise difficult or uneconomical to make by other methods. The casting process could be a sand, mold, die or any other casting processes.

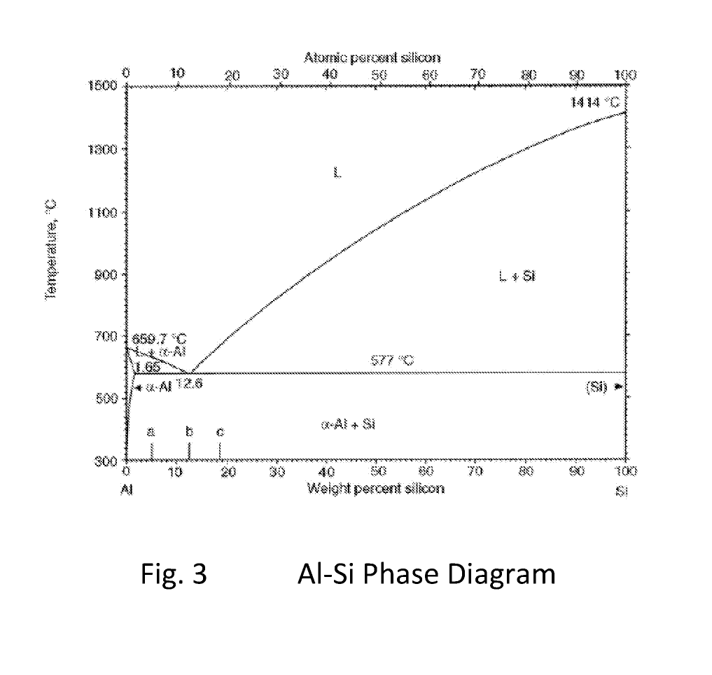

Great efforts have been long made to form a toroidal plasma chamber using the metal casting process without success. Most of the previous work of such an effort used an Al—Si cast alloy. The Al—Si alloy has obvious advantages: 1) silicon is the most available element in the world and therefore is cheap and 2) Al—Si alloy has a very low melting point and its melted alloy has the best fluidity therefore can easily form fully dense and complicated shapes. However, Si does not dissolve into the aluminum and neither will be anodized. A typical Al—Si cast alloy contains over 10% Si to take the advantage the 12.6% Si of a eutectic point as shown in FIG. 3. Such an alloy has the lowest melting temperature that is needed for an excellent fluidity required in a metal casting process. Therefore a coating layer made from an anodization process for an Al—Si cast alloy will remain more than 10% not anodized, leading to a poor quality of coating that will be easily eroded and cause chamber damage and contamination.

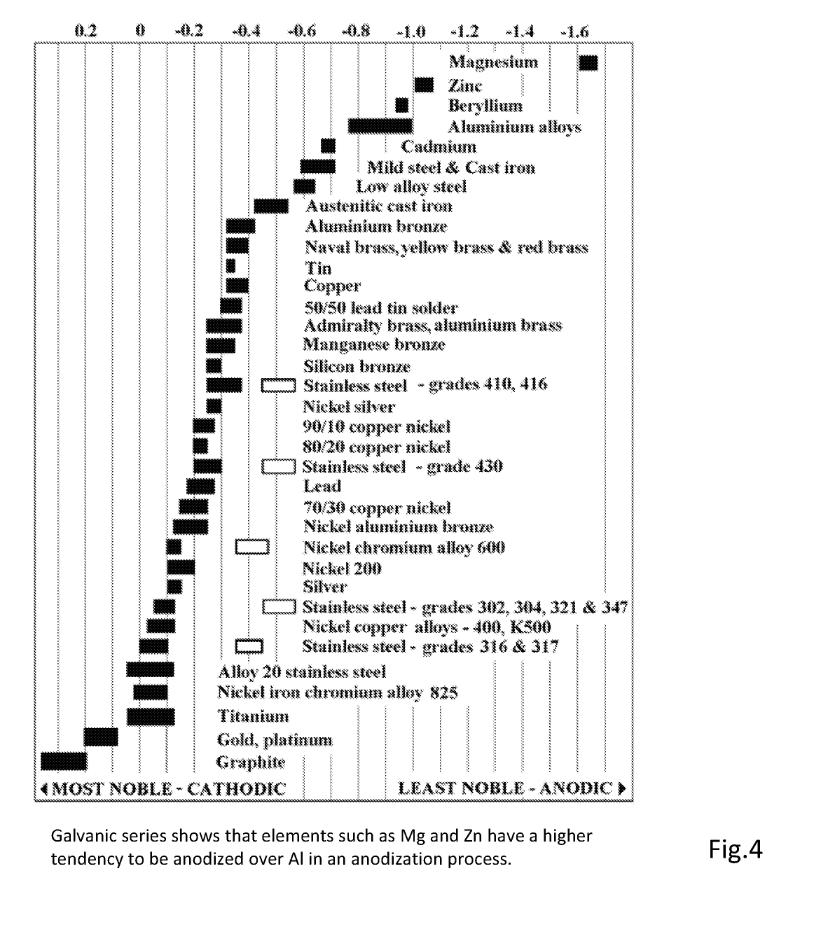

The choice of the alloy associated with the casting process is an important aspect in this invention. The alloy of this invention is an aluminum base alloy that contains elements such as Mg and Zn. Other than Si, elements like Mg and Zn are listed over Al at the anodic side in the galvanic series and will have a higher tendency to be anodized than Al, as shown in FIG. 4. So, using an alloy such as Al—Mg, Al—Zn, Al—Mg—Zn or such will make it possible to form a fully dense anodization layer with uniformly distributed microstructures. This is impossible for the most popular Al—Si casting alloy system, in which Si cannot be anodized and a large quantity of Si in the alloy will cause a loose coating layer and therefore early failure due to particle peeling and contamination.

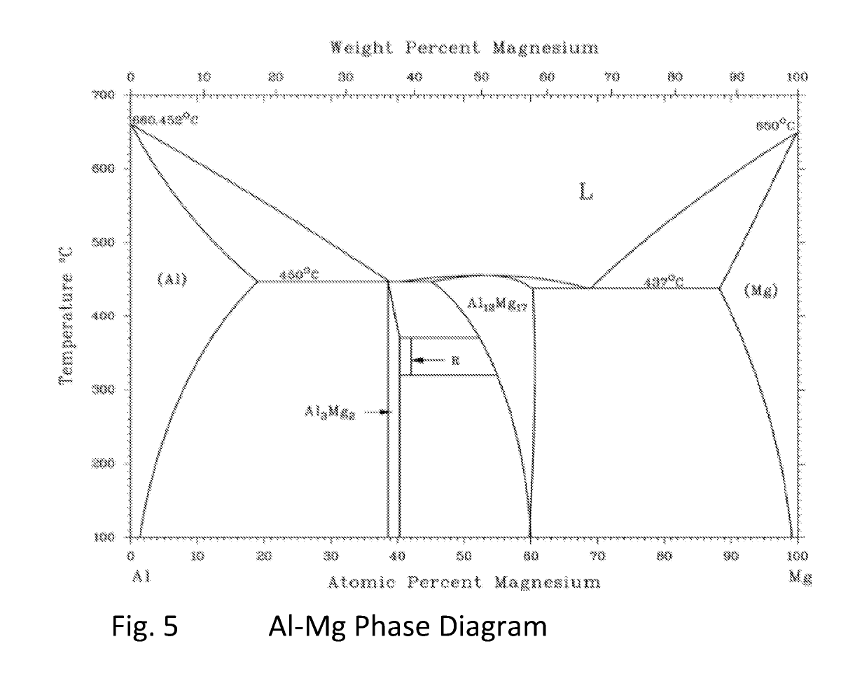

FIG. 5 is an Al—Mg phase diagram showing a eutectic melting point at 450° C. at which the maximum solubility of Mg in an Al solid solution is 17.1%. A commercial Al—Mg (500 series) alloy contains 0.5-13% Mg, typically 5-7% Mg. Since Mg is preferably anodized over Al, both Al and Mg in the alloy may be fully anodized to form a dense coating in the plasma chamber. This feature of the Al—Mg or Al—Zn alloy or such may make a fundamental difference compared with that of an Al—Si alloy, therefore make the metal casting process successful for an Al—Mg or Al—Zn alloy but not for an Al—Si alloy.

A typical metal casting process of an Al—Mg can be described as the following. When an Al—Mg (5-7% Mg) alloy is poured into a mold and solidified, all the Mg in the alloy may remain in an Al solid solution during the cooling until about 300° C. at which Mg starts to precipitate. At this stage, it is important to get a fully dense solidification through controlling the cooling speed in solidification and allow for the liquid metal to fully fill into cavities.

After the solidification process, a heat treatment process is necessary and may include: 1) heating: heat the part to a temperature between 300 and 450° C.; 2) solution treatment: hold the part at the temperature for a certain time; 3) rapid cooling: rapidly cool the part to a room temperature through a forced cooling media such as air or liquid; and 4) anneal the part at a temperature 100-200° C. to release residue stress and fine Al/Mg precipitates. Step 4) is optional depending on the Mg content and microstructure. This will allow the microstructure to contain mainly aluminum and if any, there will be a small amount of fine Mg precipitates well distributed in the Al matrix. This is a desired microstructure for an anodization process to produce a dense and uniform dielectric layer.

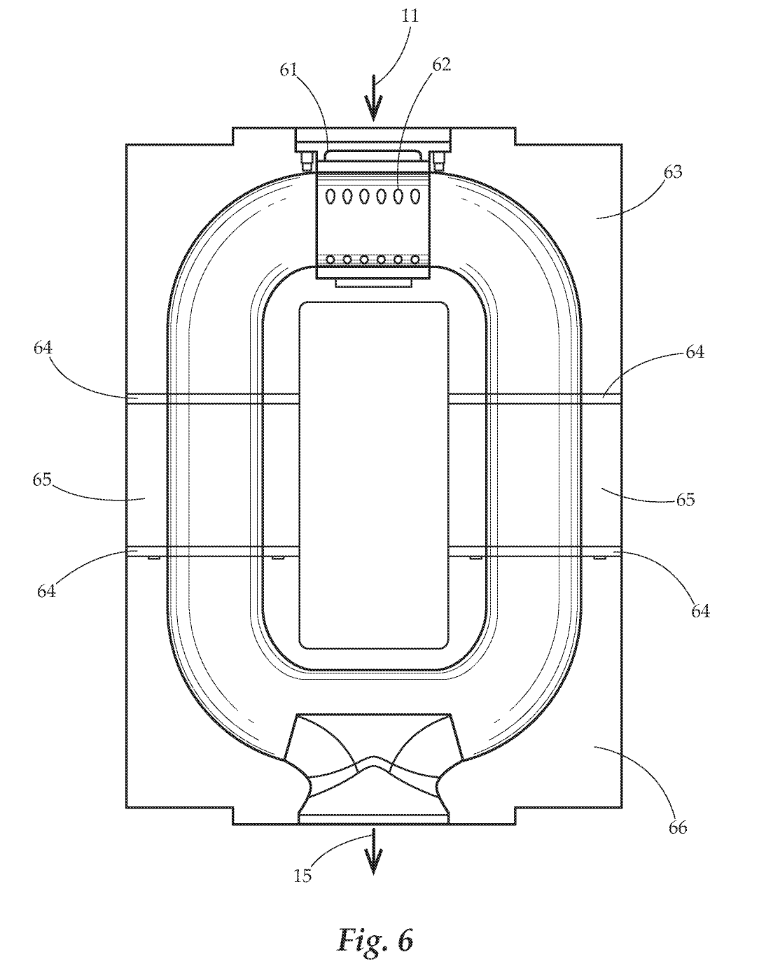

A desired shape of an inner contour of a toroidal plasma chamber is schematically illustrated in FIG. 6. First the inner contour of the chamber is smooth with no sharp corners for gas to pass and second the shape of the loop is very compatible with a profile of the current induced in the chamber that functions as a secondary wiring in the transformer. Such a desired plasma chamber may then be formed using the metal casting process with an associated aluminum alloy.

Furthermore, in the gas inlet area, there are injectors that force a gas to enter the chamber at a tangent angle to the inner surface and in a number of directions that are symmetric to the loop central line. This is also impossible or extremely difficult in a toroidal chamber made of machined parts only.

Such a toroidal plasma chamber may include some cooling features built in the chamber, such as a closed or partly closed channel through which a cooling media such as water may flow in and out and then cool the chamber. These and other features can be easily built into the plasma chamber with a metallic casting process.

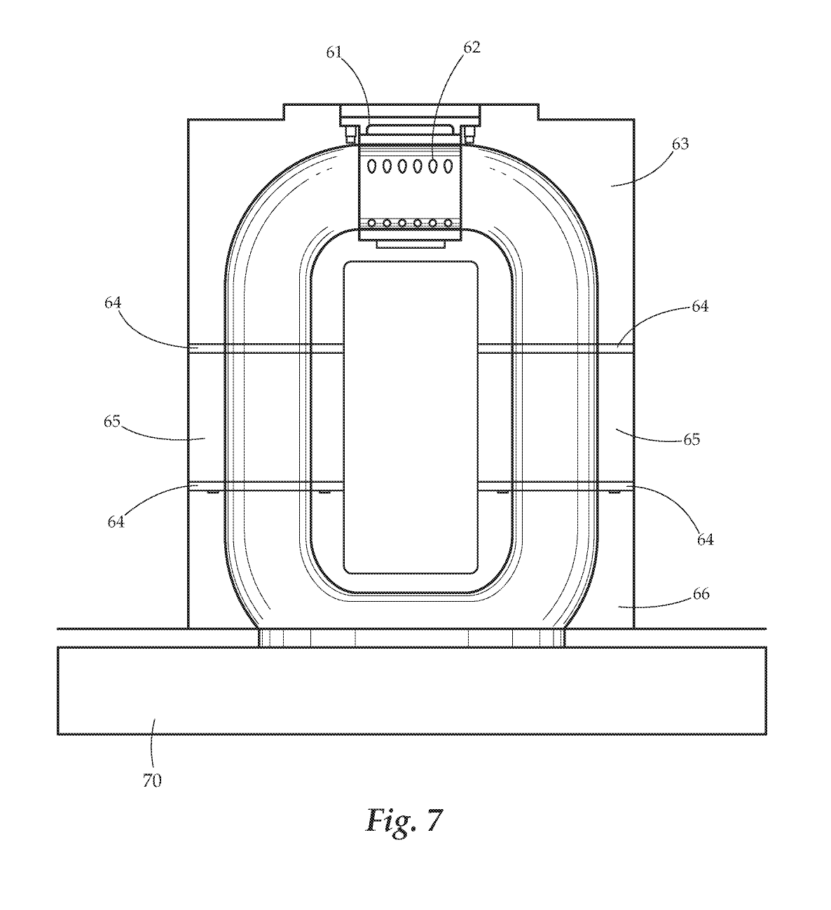

FIG. 7 is a schematic presentation of another version of this invented toroidal plasma chamber when it is used for an on-chamber wafer application or such. In such an application, the wafer process chamber may be used as part of the plasma loop for the induced current to complete. The advantage for this layout is that it minimizes the distance an activated gas has to travel before it reaches the wafer to be processed, which will increase the efficiency of the process and minimize some unnecessary erosion along the gas traveling path.

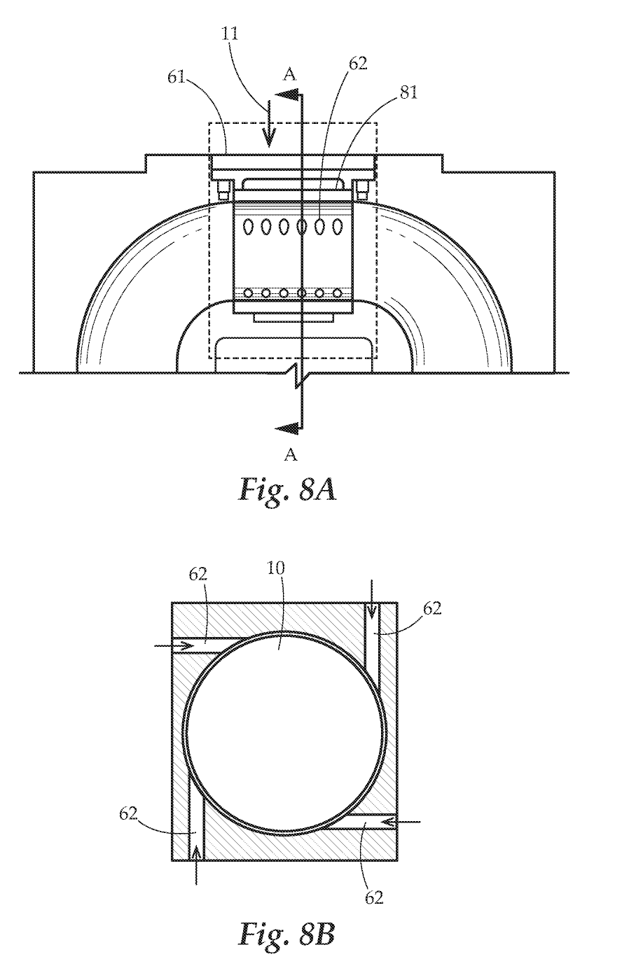

FIG. 8 is a schematic representation of the inlet area of the toroidal plasma chamber. A component made of a metallic or dielectric material with a number of groups of injectors (4 groups and 6 injectors in each group shown in FIG. 8 as an example) may be inserted into the top of the chamber as a part of the chamber loop. Gas is entered through these injectors in a tangent angle in directions that are symmetric to the central line of the chamber loop, as shown in the section view in FIG. 8. The gas so injected will flow in a swirling pattern along the inner surface of the chamber, keeping the plasma from the chamber and therefore protect the plasma chamber. This feature may enhance the compatibility of the chamber with the activated gas, especially for those aggressive gases such as Cr₂ and H₂ with which no sufficient coating material so far has been established.

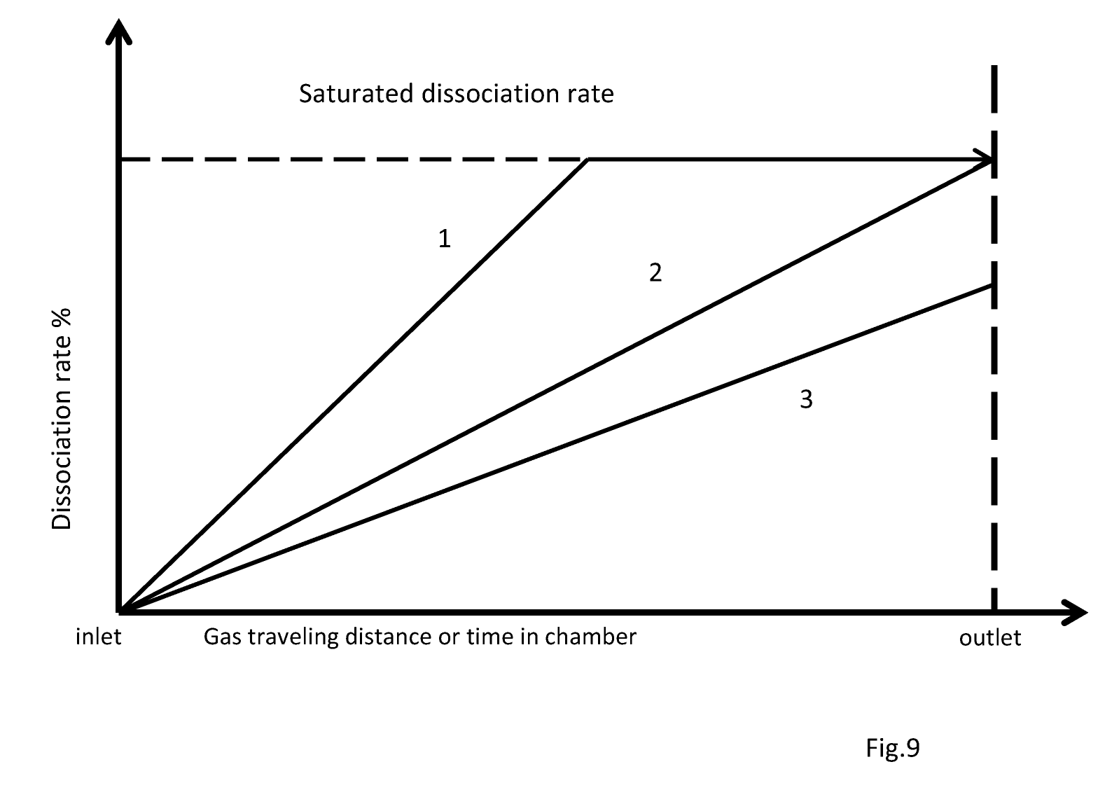

FIG. 9 is a schematic presentation of three typical gas dissociation profiles as a function of the distance along the gas flow path in a toroidal plasma chamber, depending on the power supply, gas conditions and plasma chamber size. When a fresh gas enters the plasma chamber, there are theoretically no ions or free electrons in the gas. The gas gets coupled with the field and energized in the chamber. When the energy is high enough, gas is ionized and large molecules are broken into small ones and form various combinations of free electrons, molecules, ions and radicals that are called plasma. The dissociation rate of a gas increases with an increase in the distance of the gas path in the chamber.

Curve 1 in FIG. 9 represents the situation when the gas dissociation rate reaches its saturated level, or the highest possible before it exits the chamber. The highly dissociated gas has a high level of energy and is very reactive. The plasma in such a situation is very erosive to the plasma chamber. In general, a high dissociation rate is a good property of the reactive gas as the product of the plasma process, but a highly erosive to the chamber is not desired. Curve 2 represents a situation when the gas dissociation rate reaches its saturated level, or the highest possible right at the exit of the chamber. This is an ideal situation in which a highly dissociated gas is obtained with a minimal potential damage to the plasma chamber. The gas represented by Curve 3 does not reach its highest level of dissociation at the chamber exit. In this case, the potential erosion to the chamber is minimal but the gas dissociation rate is disappointing.

The dissociation rate of a gas is a function of the power supplied, the gas, its flow rate, and the plasma chamber size. A high power, a low binding energy gas, a low flow rate and a long plasma chamber enhance the gas dissociation rate, and vice versa. As a plasma applicator is supposed to process a variety of gases at different flow rates, it is very difficult to manufacture a high performance and long lasting plasma chamber for all the gases under various conditions.

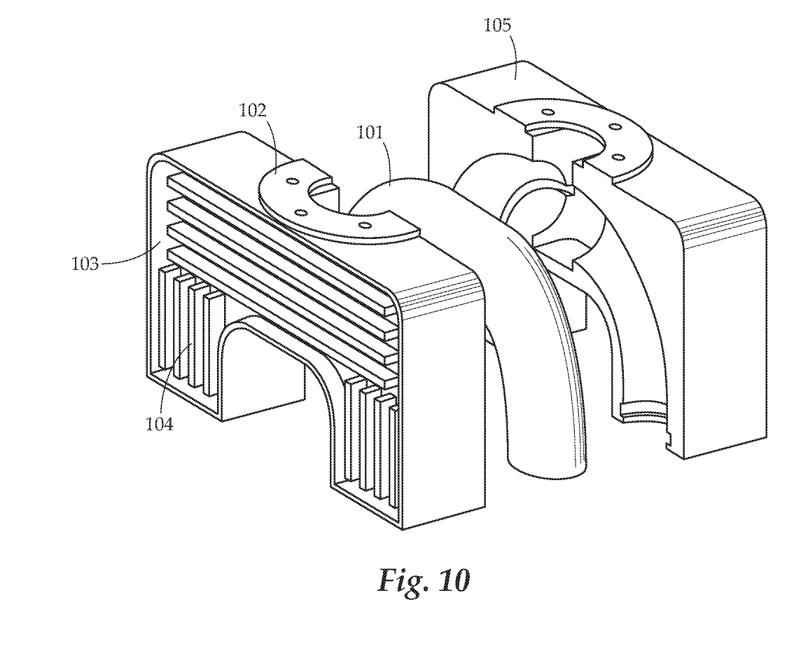

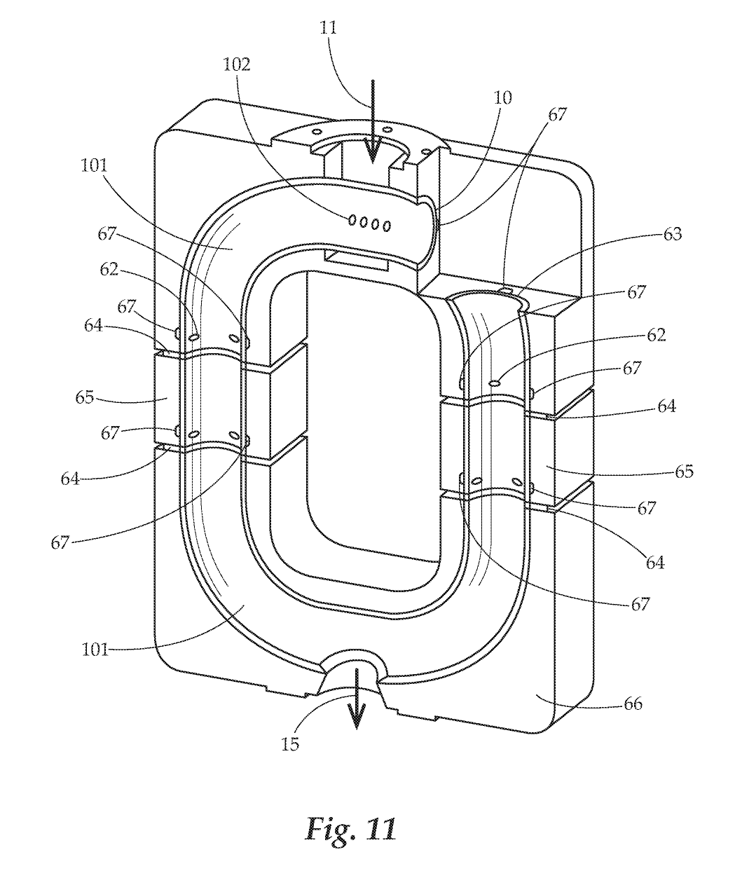

FIG. 10 is a schematic illustration of a top piece of the toroidal plasma chamber that may be formed using a tube and two sides. FIG. 11 is a schematic illustration of a sectioned toroidal plasma chamber using bent tubes with associated other parts. The chamber may consist of one or several bent tubes to make a smooth gas loop passage in a toroidal plasma chamber. Using a tube of the same aluminum alloy such as Al-6061 that has been well approved will not cause any problem in a following coating process such as anodization. Due to the bent tubes that are associated with other parts, the chamber may integrate gas channels, mounting, cooling, seal and other features for advanced functions. These tube and non-tube parts may be assembled together using a joining process to form an integrated component as a part of the toroidal plasma chamber. A great advantage of the tube bending process is the ability to build a gas injection system all the way along the chamber. A gas may be injected at different stages of the chamber and the amount of gas may be controlled through the channels built in these parts once assembled.

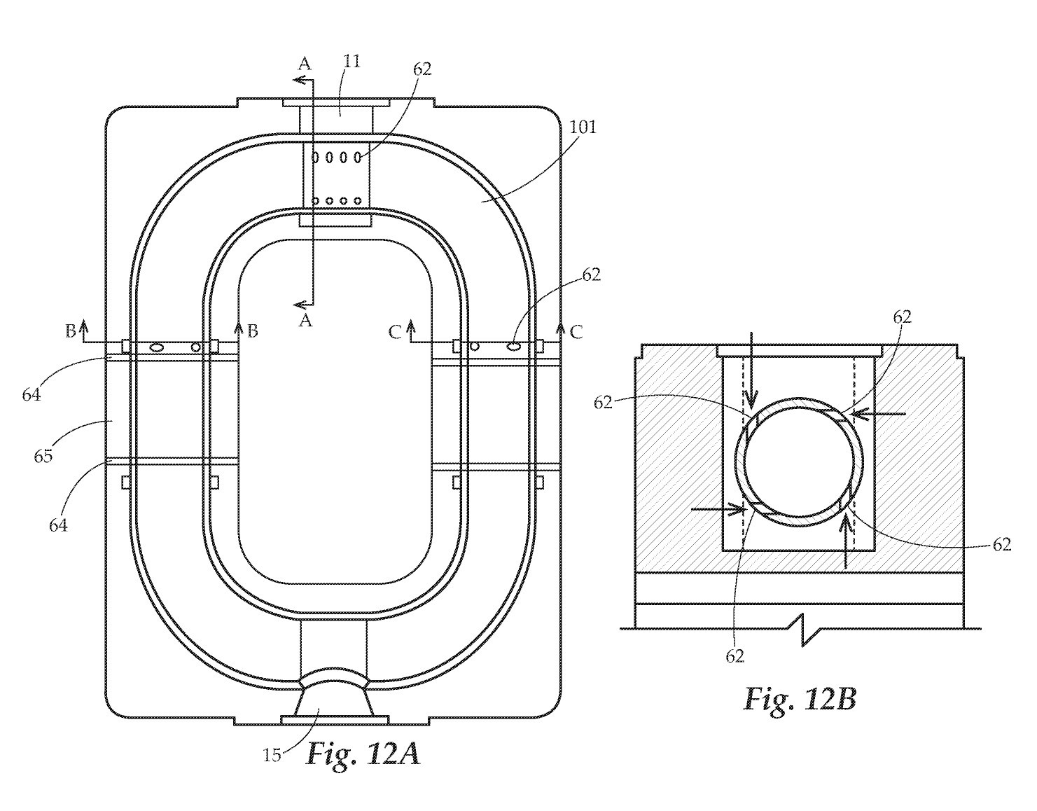

FIGS. 12a) and b) are schematic illustrations that at any locations where a gas is injected into the plasma chamber, the gas enters the chamber in symmetric orientations to the tube central line to maintain a plasma current in the center of the plasma loop and therefore to protect the chamber from severe erosion.

A fresh gas entering at the chamber has a zero dissociation rate and a fairly high resistance for the plasma current to pass through. A plasma current always avoids a freshly injected gas at the inlet for a lower resistant path. The observation is that a gas injected into the chamber pushes the plasma current away from its chamber inner surface. However, if a gas is only injected at the top of a chamber, once the gas gets highly dissociated at a later stage in the chamber, the function of such a “pushing force” offered by a fresh gas does not exist anymore.

Compared with the casting process, the tube bending process can easily build an integrated gas injection system along the plasma chamber and therefore it can protect the chamber all the way from the inlet to exit. However, an “all the way” gas injection is obviously not a best choice as the product of a plasma applicator is in general a plasma with a high dissociation rate. An appropriate combination of the tube bending and casting processes may cover all the requirements for a plasma for all gases of all conditions.

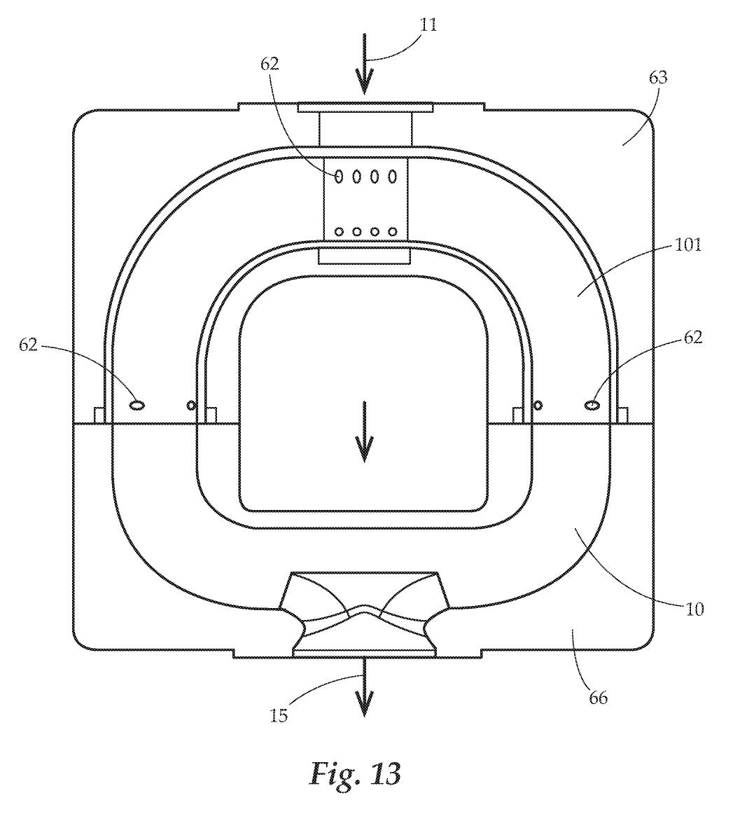

FIG. 13 is a schematic toroidal plasma chamber comprised of the top and bottom pieces, which is formed using a combined casting and tube bending process. This combination will take advantages of the integrated gas injection system from the tube bending process and a low cost with complex features from the casting process. For example, a plasma chamber with only the top and bottom two casting pieces should be enough for a less aggressive gas in a low flow rate range. Tube bending pieces may be used for a more aggressive gas. Middle pieces may be added to extend the chamber length for a large gas capacity or high gas flow rate.

Turning again specifically to the figures, FIG. 1 provides a view of an embodiment of a plasma source having a toroidal plasma chamber of the present invention. In this embodiment, the toroidal plasma chamber 10 includes a gas inlet 11 and a gas outlet 15. This plasma source includes a RF power supply 13 coupled to the chamber 10 through a primary wiring 12 and a magnetic core 14. The magnetic core 14 is positioned around a portion of the chamber 10. The current driven by the primary wiring 12 induces the potential in the toroidal plasma chamber that forms a plasma which completes the secondary circuit of the transformer, dissociates the gas passing through the chamber and produces a combination of ions, free radicals, atoms and molecules for different applications.

FIG. 2 provides a prior art view of a typical toroidal plasma chamber. As can be seen, there are a plurality of sharp corners 21 which, as noted above, can result in damage and lower quality plasma production. As can be visualized, gas enters the inlet 11 and is cycled about the chamber having the sharp edges 21, exiting through outlet 15. When passing over the sharp edges 21, the chamber is damaged, and undesirable components can be picked up by the plasma.

Turning to FIG. 6, a desired shape of an inner contour of a toroidal plasma of the present invention can be seen. In this view, the gentle curve of the corners is demonstrated. Further, in this embodiment, the chamber is formed of three sections, a top chamber 63, mid chamber 65, and bottom chamber 66. The gas inlet 11 is positioned on the top chamber 63, while the outlet 15 is positioned on the bottom chamber 66. A diffusor 61 is positioned on the inlet. Further, a plurality of injectors 62 are distributed over a portion of the chamber 10. As discussed above, these injectors are directed to inject the gas at a tangent angle to the cross section of the chamber, allowing the gas to be directed along a cross-sectional perimeter of the chamber. Ceramic portions operate as the dielectric material, either as a coating, region, or the like, for the chamber. FIG. 7 provides a similar view to that of FIG. 6, having the outlet 15 directly connected to a wafer process chamber 70.

FIGS. 8A and 8B provide a view of an exemplary top chamber 63 of the present invention. In this view, the gas inlet 11 has a diffusor 61 and injectors 62. These injectors 62 are positioned on an inserted injection piece 81. As seen in FIG. 8b, this injection piece 81 has a plurality of injectors each aligned to direct inlet gas flow at a tangent angle to the cross section of the chamber. In this view, the injectors 62 are aligned in a plane, however they may be staggered along the length of the chamber as well without straying from the scope of this invention.

FIG. 10 provides an exploded view of a portion of the chamber. This particular embodiment may be particularly useful for a bent tube embodiment, but not necessarily limited to such. Here, a left and right half 103, 105 are shown spread apart, having the bent tube 101 which defines the chamber between the two. Each side 103, 105 defines an inlet mounting fitting 102. Cooling fins 104 are shown on the left side 102, and may also be on the right side 105.

FIG. 11 provides another cutaway view of an embodiment of the present invention. Here, the chamber includes a top piece 63, middle piece 65 and bottom piece 66. Ceramic portions 64 function here as the dielectric material. The metallic tube 101 extends in a toroidal shape to define the gas passage chamber 10. In varying embodiments, the tube 101 may be formed of multiple different portions with dielectric pieces between them because a toroidal chamber cannot form a continuous loop itself or the induced plasma current will pass through the solid chamber instead of the gas that passes through it. Injector tube portion 102 has injectors 62 as discussed above. Built in gas channels 67 in top, middle, and bottom pieces 63, 65, 66 allow gas to flow to the injectors 62.

FIG. 12 provides a cross sectional view of an embodiment of the toroidal plasma chamber having injectors spaced along a length of the chamber in various positions. As can be seen, a plurality of injectors 62 are arranged not just adjacent to the inlet 11 but also on a left and right side of the chamber, close to the middle section 65. As seen in FIG. 12b, this injection piece 81 has a plurality of injectors each aligned to direct inlet gas flow at a tangent angle to the cross section of the chamber.

FIG. 13 provides a view of another embodiment of the present invention having part of the chamber formed by a cast process and the remainder of the chamber formed as a bent tube. In this embodiment, the inlet top portion 62 is formed as a bent tube, while the outlet bottom portion 66 is formed by casting. As discussed above, this provides multiple potential advantages, depending on the needs of the plasma system.

While several variations of the present invention have been illustrated by way of example in preferred or particular embodiments, it is apparent that further embodiments could be developed within the spirit and scope of the present invention, or the inventive concept thereof. However, it is to be expressly understood that such modifications and adaptations are within the spirit and scope of the present invention, and are inclusive, but not limited to the following appended claims as set forth.

What is claimed is:

1. A method of making a toroidal plasma chamber comprising the steps of:
melting a quantity of metal, the quantity of metal being a metal or metal alloy;
obtaining a mold configured to form at least part of the toroidal plasma chamber;
conveying the melted quantity of metal to the mold;
allowing the melted quantity of metal to solidify in the mold;
removing the solidified quantity of metal from the mold, wherein the solidified quantity of metal defining at least part of the toroidal plasma chamber, and defining at least one of a gas inlet and gas outlet; and
machining the solidified quantity of metal to form required features such as fittings, cooling channels, mounting holes or surface finish required that a metal casting process alone cannot provide.

2. The method of claim 1 wherein the quantity of metal is an alloy selected from the group consisting of Al—Mg; Al—Zn; and Al—Mg—Zn.

3. The method of claim 1 wherein the quantity of metal may be an Al—Mg alloy having a quantity of Mg of approximately 5-7%.

4. The method of claim 1 wherein the quantity of metal may be either an Al—Zn alloy having a quantity of Zn of approximately 0.5-13%.

5. The method of claim 1 further comprising the step of heating the at least part of the toroidal plasma chamber to a temperature between 300 and 450° C.

6. The method of claim 5 further comprising the step of holding the at least part of the toroidal plasma chamber for a predetermined period of time.

7. The method of claim 6 further comprising the step of rapidly cooling the at least part of the toroidal plasma chamber to a room temperature through a forced cooling media after the holding step.

8. The method of claim 7 further comprising the step of annealing the at least part of the toroidal plasma chamber at a temperature of approximately 100-200° C. to release residue stress and fine Al/Mg precipitates if an Al—Mg alloy is selected, or fine Al/Zn precipitates if an Al—Zn alloy is selected, the annealing being performed after the cooling step.

9. The method described in the above claims may be utilized to form part, or a whole toroidal plasma chamber that comprises of multiple such formed cast components with dielectric pieces between them in a finally assembled chamber.

10. The method of claim 9 comprising an injection component inserted into the inlet part of the toroidal plasma chamber and the injection component can be made of dielectric, metal or alloy materials.

11. A method of making a toroidal plasma chamber comprising the steps of:
obtaining a tube;
bending the tube into a desired shape for a part of the toroidal plasma chamber, wherein the bent tube defining at least part of the toroidal plasma chamber, and defining at least one of a gas inlet and gas outlet;
machining the tube to obtain require features such as injection holes, gas channels and joint features;
joining the tube with none-tube parts to form subassemblies with required features such as fittings, mounting features, cooling channels as part of the toroidal chamber;
forming, in the tube, a plurality of injectors, the plurality of injectors each configured to inject a quantity of gas in a direction that is at a tangent angle to an inner surface of at least part of the toroid shaped chamber; and
wherein tube is formed of an alloy selected from the group consisting of a wright aluminum alloy such as an Al-6061 or Al-6063 alloy.

12. The method of claim 11 may be utilized to form part, or a whole toroidal plasma chamber that comprises of multiple such formed tube components with dielectric pieces between them in a finally assembled toroidal plasma chamber.

13. The method of claim 12 comprising an injection system integrated in the toroidal plasma chamber including its inlet in which a gas can be injected at any location of the toroidal plasma chamber.

14. The method in claim 13 comprising gas inlet, gas channels and injection holes to inject a gas into the chamber built in the tube and none-tube components and becoming functional after these components being joined together as an integrated assembly.

15. A method of making a toroidal plasma chamber comprising the steps of:
obtaining a cast metal or alloy component or a number of cast components that are formed as in the method of claims 1-10;
obtaining a tube subassembly, or a number of tube subassemblies that are formed as in the method of claims 11-14;
assembling these cast and tube components and subassemblies as an integrated toroidal plasma chamber that has a desired curve inner surface, a gas inlet and a gas outlet.

16. The plasma chamber of claim 15 further comprising a gas injector, the gas injector configured to inject a quantity of gas in a direction that is at a tangent angle to an inner surface of the at least part of the toroid shaped chamber.

17. The plasma chamber of claim 15 wherein an inner surface of the toroidal plasma chamber is anodized.

18. The plasma chamber of claim 15 wherein part of the toroidal plasma chamber is formed of an alloy selected from the group consisting of Al-6061 and Al-6063 wright alloy if that part is formed of a bent tube or an assembly of bent tube components.

19. The plasma chamber of claim 15 wherein part of the toroidal plasma chamber is formed of an alloy selected from the group consisting of Al—Mg; Al—Zn; and Al—Mg—Zn if the part is formed of a cast metal or alloy.

20. The plasma chamber of claim 16 further comprising a plurality of gas injectors, the plurality of gas injectors configured to inject a quantity of gas in a direction that is at a tangent angle to an inner surface of the at least part of the toroid shaped chamber, one of the plurality of gas injectors in a first flow position on the chamber, a second of the plurality of gas injectors in a second flow position on the chamber that is closer to the outlet than the first of the plurality of gas injectors.

21. The plasma chamber of claim 20 wherein the injector is configured to inject a same or a mixed gas as a gas entering the plasma source from the inlet.
